(19) United States
(12) Patent Application Publication
(10) Pub. No.: US 2025/0241056 A1
(43) Pub. Date: Jul. 24, 2025

(54) ELECTRONIC DEVICE

(71) Applicant: STMicroelectronics International N.V., Geneva (CH)

(72) Inventor: Karl GRANGE, Tours (FR)

(21) Appl. No.: 19/014,964

(22) Filed: Jan. 9, 2025

(30) Foreign Application Priority Data
Jan. 23, 2024 (FR) FR2400632

(51) Int. Cl. H10D 84/80; H01L 23/00; H10D 8/00; H10D 84/00

(52) U.S. Cl. CPC H10D 84/811; H01L 24/05; H10D 8/411; H10D 84/221; H01L 2224/04042

(57) ABSTRACT

An electronic device is provided comprising a substrate and at least one first input/output pad, each first pad being coupled to the substrate by an assembly, each assembly comprising first and second wells, the first well being located in the second well, the second well being located in the substrate, the substrate and the first well being doped with a first conductivity type, the second well being doped with a second conductivity type opposite to the first conductivity type, each assembly being configured so that the threshold voltage of the diode formed by the first and second wells is lower than the threshold voltage of the diode formed by the second well and the substrate when the first conductivity type is type P, or higher than the threshold voltage of the diode formed by the second well and the substrate when the first conductivity type is type N.

### CROSS REFERENCE TO RELATED APPLICATION

This application is a translation of and claims the priority benefit of French patent application number 2400632, filed on Jan. 23, 2024, entitled “Dispositif électronique,” which is hereby incorporated by reference to the maximum extent allowable by law.

### TECHNICAL FIELD

The present description generally concerns electronic devices and more specifically input and output connections of electronic devices.

### BACKGROUND

In semiconductor electronic devices receiving external voltages, the reference voltage is, for example, the voltage having the substrate biased thereto.

In certain electronic devices, the application of voltages lower than the reference voltage may cause leakages which are not present when voltages higher than the reference voltage are applied. In other electronic devices, the application of voltages higher than the reference voltage may result in leakages which are not present when voltages lower than the reference voltage are applied.

### BRIEF SUMMARY

An embodiment overcomes all or part of the disadvantages of known electronic devices.

An embodiment provides an electronic device comprising a substrate and at least one first input/output pad, each first input/output pad being coupled to the substrate by an assembly, each assembly comprising first and second wells, the first well being located in the second well, the second well being located in the substrate, the substrate and the first well of each assembly being doped with a first conductivity type, the second well of each assembly being doped with a second conductivity type opposite to the first conductivity type, each assembly being configured so that the threshold voltage of the diode formed by the first and second wells of the assembly is (i) lower than the threshold voltage of the diode formed by the second well and the substrate when the first conductivity type is type P or (ii) higher than the threshold voltage of the diode formed by the second well and the substrate when the first conductivity type is type N.

According to an embodiment, the first well of each assembly is coupled to the substrate by an element external to the substrate.

According to an embodiment, the first well of each assembly is coupled to the substrate by a wire element.

According to an embodiment, the device comprises at least two first input/output pads.

According to an embodiment, the first well of each assembly is separated from the substrate by the second well of the same assembly.

According to an embodiment, the device comprises a second input/output pad coupled to the substrate by an assembly, the second pad being configured to receive a reference voltage.

According to an embodiment, the reference voltage is a zero potential.

According to an embodiment, the first input/output pads are coupled to an electronic circuit.

According to an embodiment, the electronic circuit comprises bipolar transistors.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an electronic device according to an embodiment; and

FIG. 2 schematically shows the device of FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

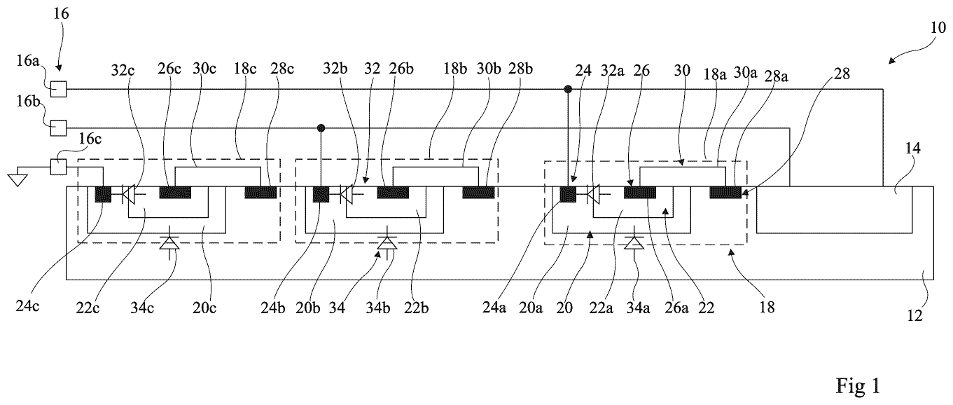

FIG. 1 shows an electronic device 10 according to an embodiment.

Device 10 corresponds, for example, to an electronic chip. Device 10 comprises a semiconductor substrate 12. Substrate 12 is for example made of silicon. Substrate 12 is doped with a first conductivity type, for example type P.

Device 10 comprises at least one electronic circuit 14. Circuit 14 is for example configured to carry out at least one function. Circuit 14 is, for example, a power management circuit. More precisely, device 10 comprises electronic components forming circuit 14. The electronic components of circuit 14 are, for example, formed inside and on top of substrate 12. Device 10 is for example an electronic control device intended to be integrated into electrical, electromechanical or optoelectronic equipment. The device 10 is for example intended to be integrated into industrial equipment, home appliances, or automobile equipment, for controlling such equipment. The device 10 is for example suitable for controlling equipment via wired buses of the LIN or CAN type. The device 10 is for example suitable for controlling equipment according to the IEC 61131-2 standard.

Circuit 14 is coupled to at least one input/output pad 16, preferably an input pad. In the example of FIG. 1, circuit 14 is connected to two input/output pads 16a and 16b. Each of the two input/output pads 16 is for example configured to receive an input voltage. Similarly, circuit 14 is configured to receive the input voltages. For example, at least one pad 16 is coupled, preferably connected, to a terminal of a transistor of circuit 14, for example a bipolar transistor, a MOSFET transistor or another type of transistor.

Device 10 also comprises an input/output pad 16c. Pad 16c is configured to receive a reference voltage, for example the ground. Pad 16c is for example configured to receive a zero potential.

Each input pad 16 is further coupled to substrate 12 via an assembly 18. More specifically, pad 16a is coupled to substrate 12 by an assembly 18a. Pad 16b is coupled to substrate 12 by an assembly 18b. Pad 16c is coupled to substrate 12 by an assembly 18c. Preferably, device 10 comprises no input/output pad directly connected to substrate 12.

Each assembly 18 comprises a first well 20. The well is located in substrate 12. Well 20 is preferably flush with an upper surface of substrate 12. Well 20 is made of a semiconductor material, for example the same material as substrate 12. Well 20 is doped with the conductivity type opposite to the conductivity type of substrate 12. Well 20 is, for example, N-doped.

Each assembly 18 further comprises a well 22 located within well 20. Well 20 is preferably flush with an upper face of well 20. The upper surfaces of substrate 12 and of wells 20 and 22 are for example coplanar. Well 22 is for example totally surrounded by well 20, except for its upper surface. Well 22 is entirely separated from substrate 12 by well 20. Well 22 is made of a semiconductor material, for example the same material as substrate 12 and as well 20. Well 22 is doped with the conductivity type opposite to the conductivity type of well 20, that is, the same conductivity type as substrate 12. Well 22 is for example P-type doped.

Thus, assembly 18a comprises wells 20 and 22, designated with references 20a and 22a, such as previously described. Assembly 18b comprises wells 20 and 22, designated with references 20b and 22b, such as previously described. Assembly 18c comprises wells 20 and 22, designated with references 20c and 22c, such as previously described.

Each assembly 18 further comprises a contact 24. Contact 24 is located in the well 20 of the same assembly 18. Contact 24 for example corresponds to a region of the well 20 of the same assembly, more heavily doped than the rest of well 20. Contact 24 is coupled, preferably connected, to the pad 16 associated with the assembly 18 of contact 24. The contact 24 of at least some of assemblies 18, for example of all the assemblies other than assembly 18c, is for example coupled, preferably connected, to circuit 14. Thus, the well 20 of each assembly 18 is biased to the voltage delivered on the pad 16 associated with assembly 18.

Each assembly 18 further comprises a contact 26. Contact 26 is located in the well 22 of the same assembly 18. Contact 26 corresponds, for example, to a region of the well 22 of the same assembly, more heavily doped than the rest of well 22.

Each assembly 18 also comprises a contact 28. Contact 28 is located in substrate 12, for example around well 20. Contact 28 corresponds, for example, to a region of substrate 12, for example a region of the substrate around well 20, more heavily doped than the rest of substrate 12.

The regions that form contacts 26 and 28 of a same assembly 18 are coupled, preferably connected, preferably by a connection element external to the substrate 12. For example, the regions that form contacts 26 and 28 of a same assembly 18 are coupled, preferably connected, by a wire connection element 30, for example a metal wire.

In the case of the device 10 of FIG. 1, assembly 18a comprises contacts 24, 26, 28, designated with references 24a, 26a, and 28a, and a connection element 30, designated with reference 30a, such as previously described. Assembly 18b comprises contacts 24, 26, 28, designated with references 24b, 26b, and 28b, and a connection element 30, designated with reference 30b, such as previously described. Assembly 18c comprises contacts 24, 26, 28, designated with references 24c, 26c, and 28c, and a connection element 30, designated with reference 30c, such as previously described.

The PN junction located between the wells 20 and 22 of a same assembly 18, that is, the PN junction formed at the interface between the wells 20 and 22 of a same assembly 18, forms a diode 32. Similarly, the PN junction located between the well 20 of an assembly and the substrate 12 surrounding the assembly 18, that is, the PN junction formed at the interface between the well 20 of an assembly and the substrate 12 surrounding the assembly 18, forms a so-called parasitic diode 34. As an illustration, diodes 32 and 34 are schematically represented by their symbols in FIG. 1.

In the example shown in FIG. 1, the doping levels of substrate 12 and of wells 20 and 22 are selected so that the saturation current of the diode 32 of an assembly 18 is greater by at least a decade than the saturation current of the diode 34 of the same assembly. For example, the PN junction between the wells 20 and 22 of a same assembly 18 is configured to be abrupt, while the junction between the well 20 of this assembly and substrate 12 is configured to be more gradual.

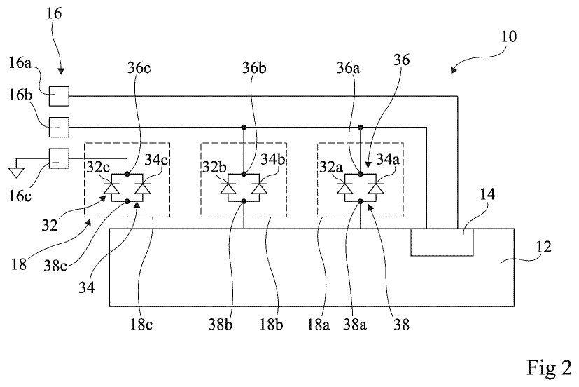

FIG. 2 schematically shows the device 10 of FIG. 1.

FIG. 2 shows, like FIG. 1, substrate 12 and the circuit 14 located in substrate 12. FIG. 2 further shows the input/output pads 16, more precisely pads 16a, 16b, and 16c, of FIG. 1. As in FIG. 1, pad 16c is coupled to a source, for example external to substrate 12, of a reference voltage.

As in FIG. 1, at least certain pads 16, for example the pads 16 other than the pad 16 receiving the reference voltage, are coupled, preferably connected, to circuit 14. Each pad 16 is further coupled to substrate 12 by an assembly 18. Each assembly 18 comprises, in FIG. 2, a diode 32 and a diode 34.

The diodes 32 and 34 of an assembly 18 are coupled in parallel between a node 36 and a node 38. Thus, diodes 32a and 34a are coupled in parallel between node 36a and node 38a. Diodes 32b and 34b are coupled in parallel between node 36b and node 38b. Diodes 32c and 34c are coupled in parallel between node 36c and node 38c. Each node 36 is coupled, preferably connected, to the pad 16 associated with assembly 18. Each node 38 is coupled, preferably connected, to substrate 12. Thus, the cathodes of the diodes 32 and 34 of an assembly are coupled, preferably connected, together and coupled, preferably connected, to the pad 16 associated with the assembly. The anodes of the diodes 32 and 34 of an assembly are coupled, preferably connected, together and coupled, preferably connected, to substrate 12.

The cathodes of the diodes 32 and 34 of an assembly 18 are formed by the well 20 of the assembly 18. The anode of the diode 34 of the assembly is formed by substrate 12. The anode of diode 32 is formed by well 22. The coupling between the anode of diode 32 and substrate 12 is formed by the connection element 30 of the assembly.

As described in relation with FIG. 1, the threshold voltage of diode 32 is lower than the threshold voltage of diode 34. Thus, during the operation of device 10, substrate 12 is biased to the lowest voltage among the voltages received on pads 16. The ground of circuit 14 is thus the lowest voltage among the voltages delivered on pads 16. The potential differences between pads 16, for example between pad 16a or 16b and pad 16c, remain identical. However, all voltages are positive voltages.

There could have been chosen not to provide assembly 18 in device 10, and thus to couple pad 16c directly to the substrate and the other pads directly to circuit 14. However, in this case, when negative voltages are applied to circuit 14 and in particular to the bipolar transistors, a high leakage current would be formed between the bipolar transistor and the substrate.

According to another embodiment, not shown, the conductivity types could be reversed. Thus, in this other embodiment, substrate 12 is N-doped, wells 20 are P-doped, and wells 22 are N-doped. Diodes 32, and the doping levels of wells 20, 22 and of substrate 12, are then configured so that the saturation current of the diode 32 is greater by at least a decade than the saturation current of the diode 34. This embodiment is for example adapted to devices where the application of a positive voltage would risk generating more significant leakage currents than the application of a negative voltage. The device for example comprises NPN-type bipolar transistors in circuit 14.

An advantage of the described embodiments is that the device generates less leakage currents.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

That which is claimed:

1. An electronic device comprising:
a substrate; and
at least one first input/output pad, each first input/output pad being coupled to the substrate by an assembly, each assembly comprising first and second wells, the first well being located in the second well, the second well being located in the substrate, the substrate and the first well of each assembly being doped with a first conductivity type, the second well of each assembly being doped with a second conductivity type opposite to the first conductivity type, each assembly being configured so that a threshold voltage of a diode formed by the first and second wells of the assembly is (i) lower than a threshold voltage of a diode formed by the second well and the substrate when the first conductivity type is type P or (ii) higher than the threshold voltage of the diode formed by the second well and the substrate when the first conductivity type is type N.

2. The device according to claim 1, wherein the first well of each assembly is coupled to the substrate by an element external to the substrate.

3. The device according to claim 2, wherein the first well of each assembly is coupled to the substrate by a wire element.

4. The device according to claim 1, wherein the device comprises at least two first input/output pads.

5. The device according to claim 1, wherein the first well of each assembly is separated from the substrate by the second well of a same assembly.

6. The device according to claim 1, wherein the device comprises a second input/output pad coupled to the substrate by an assembly, the second pad being configured to receive a reference voltage.

7. The device according to claim 6, wherein the reference voltage is a zero potential.

8. The device according to claim 1, wherein the at least one first input/output pad is coupled to an electronic circuit.

9. The device according to claim 8, wherein the electronic circuit comprises bipolar transistors.
